(19) United States
(12) Patent Application Publication
(10) Pub. No.: US 2011/0233568 A1
(43) Pub. Date: Sep. 29, 2011

(54) LED STREET LAMP

(75) Inventors: Haeng Su An, Jeonju-si (KR); Jung Suk Kim, Jeonju-si (KR)

(73) Assignee: SET Co., Ltd., Jeonju-si (KR)

(21) Appl. No.: 12/995,838

(22) PCT Filed: Oct. 8, 2009
(86) PCT No.: PCT/KR2009/005762

§ 371 Date: Jun. 14, 2011

(30) Foreign Application Priority Data
Dec. 18, 2008 (KR) 10-2008-0129052

(51) Int. Cl. H01L 33/64

(52) U.S. Cl. 257/88; 257/E33.055

(57) ABSTRACT

Disclosed is a light emitting diode (LED) street lamp using an LED as a light source and capable of minimizing a luminance deviation within an illuminated area while increasing the luminance of the entire illuminated area. The LED street lamp includes a case provided at a front end of a lamp post; a board provided inside the case and having a plurality of LEDs spaced apart from each other; and heat dissipation units closely adhered to the board and dissipating heat generated when the LEDs emit light, wherein the plurality of LEDs have different luminance levels from each other, the luminance levels gradually increase from the center of the board to the edge of the board, and diffusing members diffusing the light generated from the plurality of LEDs are provided on board portions corresponding to areas between each of the plurality of LEDs.

### CROSS-REFERENCE TO RELATED APPLICATION

This application claims priority to and the benefit of Korean Patent Application No. 10-2008-0129052, filed on Dec. 18, 2008, the entire content of which is incorporated herein by reference.

### BACKGROUND OF THE INVENTION

1. Field of the Invention

The present invention relates to a light emitting diode (LED) street lamp, and more particularly, to an LED street lamp using an LED as a light source and capable of minimizing a luminance deviation within an illuminated area while increasing the luminance of the entire illuminated area.

2. Description of the Related Art

In general, a street lamp is an illumination device installed along a road for ensuring the safety and security of a road traffic. The street lamp includes a lamp post fixed on a ground surface along a road, and a street lamp head integrally formed at an end of the lamp post to be directed toward the road. An electric lamp is provided within the street lamp head to emit light, thereby illuminating the road.

The electric lamp usually employs a bulb, shortening the service life of the electric lamp and lowering impact resistance. To overcome the disadvantages, use of a highly luminous light emitting diode (LEDs) having a considerably prolonged service life and improved impact resistance has recently become widespread.

Existing street lamps using the LED include an LED lamp disclosed in Korean Patent No. 0767738.

The disclosed LED lamp includes a case, an aluminum board provided in the case and having a plurality of LEDs mounted thereon, a plurality of coolant sheets disposed on the aluminum board and dissipating heat generated when the plurality of LEDs, a heat pipe, and heat dissipating fins.

In view of light emission characteristic, the LED has luminance that is highest at its central portion and gradually decreases from the central portion to the edge. However, since the conventional LED lamp includes a plurality of LEDs arranged on the aluminum board of a flat panel type, a high intensity of luminance cannot be illuminated to an area between adjacent street lamps, producing a blind zone.

### BRIEF SUMMARY OF THE INVENTION

In order to overcome the above-mentioned shortcomings, the present invention provides a light emitting diode (LED) street lamp, and more particularly, to an LED street lamp using an LED as a light source and capable of minimizing a luminance deviation within an illuminated area while extending the illuminated area and increasing the entire luminance of the illuminated area.

According to an aspect of the invention, there is provided a light emitting diode (LED) street lamp including a case provided at a front end of a lamp post, a board provided inside the case and having a plurality of LEDs spaced apart from each other, and heat dissipation units closely adhered to the board and dissipating heat generated when the LEDs emit light, wherein the plurality of LEDs have different luminance levels from each other, the luminance levels gradually increase from the center of the board to the edge of the board, and diffusing members diffusing the light generated from the plurality of LEDs are provided on board portions corresponding to areas between each of the plurality of LEDs.

The board may be convexly formed and each of the LEDs may be installed on a convex external surface. Alternatively, the board may be concavely formed and each of the LEDs may be installed on a concave internal surface.

The diffusing members may be made of a transparent material in the form of a polyhedron such that some of the light beams emitted from the plurality of LEDs are diffused, and protrude from the board until it reaches a position where the light beams from neighboring ones among the plurality of LEDs overlap each other.

According to another aspect of the invention, there is provided a light emitting diode (LED) street lamp including a case provided at a front end of a lamp post, a board provided inside the case and having a plurality of LEDs spaced apart from each other, heat dissipation units closely adhered to the board and dissipating heat generated when the LEDs emit light, wherein assuming that a line passing from the LEDs to the center of beam angles of light illuminated is referred to as an optical center line and an angle between optical center lines of two adjacent LEDs is a beam angle, the beam angle between the two adjacent LEDs decreases gradually from the central portion to the edge of the board.

As described above, in the LED street lamp according to the present invention, a plurality of LEDs having different luminance levels are arranged on a convex or concave surface of a board, the plurality of LEDs being arranged such that the luminance gradually increases from the center to the edge of the surface, thereby enlarging an illuminated area while preventing the overall luminance of the illuminated area from decreasing.

In addition, some of light emitted the LEDs may be diffused between two neighboring ones of the plurality of LEDs by a diffusing member, thereby increasing the luminance of the illuminated area, and prevent a blind zone between adjacent street lamps by enlarging the illuminated area without sacrificing the luminance.

Further, in a case where the LEDs have the same luminance, they are arranged such that a beam angle between two adjacent LEDs decreases gradually from the central portion to the edge of the board, thereby preventing the luminance from decreasing while enlarging the illuminated area

### BRIEF DESCRIPTION OF THE DRAWINGS

The objects, features and advantages of the present invention will be more apparent from the following detailed description in conjunction with the accompanying drawings, in which:

FIG. 1 illustrates an LED street lamp according to an embodiment of the present invention;

FIG. 2 illustrates LEDs and diffusing members arranged on a board of the LED street lamp shown in FIG. 1;

FIG. 3 illustrates an example in which some of light beams emitted from LEDs are diffused by a diffusing member on the board of the LED street lamp shown in FIG. 1;

FIG. 4 illustrates another example of a board of the LED street lamp shown in FIG. 1;

FIG. 5 illustrates an LED street lamp according to another embodiment of the present invention;

FIG. 6 illustrates an embodiment in which a diffusion lens is installed under a board;

FIG. 7 is a perspective view of an LED street lamp including a plurality of unitary LED modules;

FIG. 8 is an exploded perspective view of a unitary LED module shown in

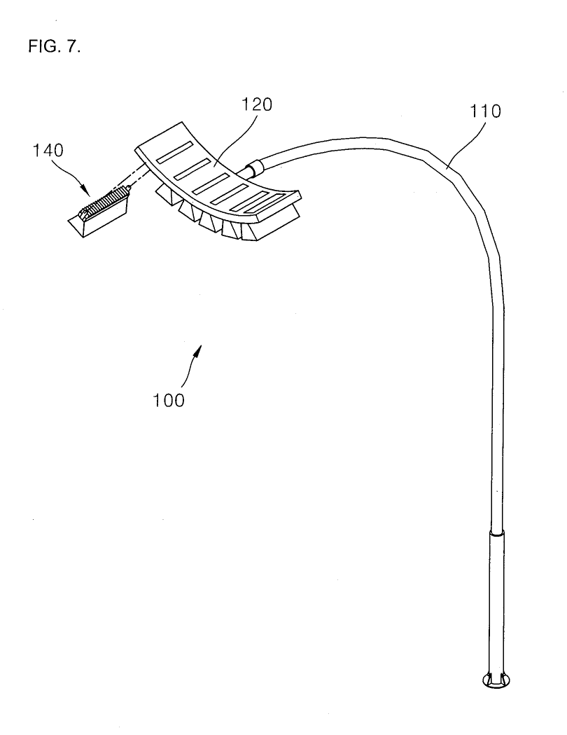

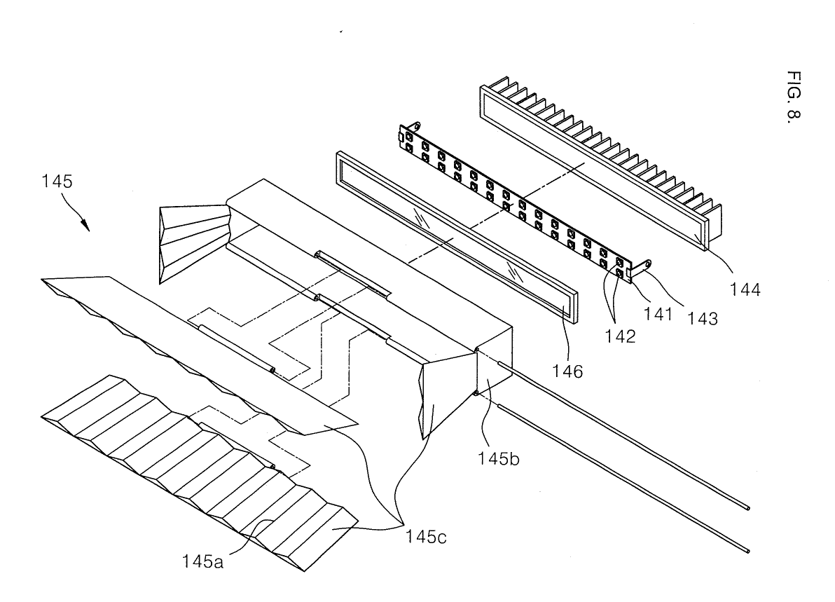

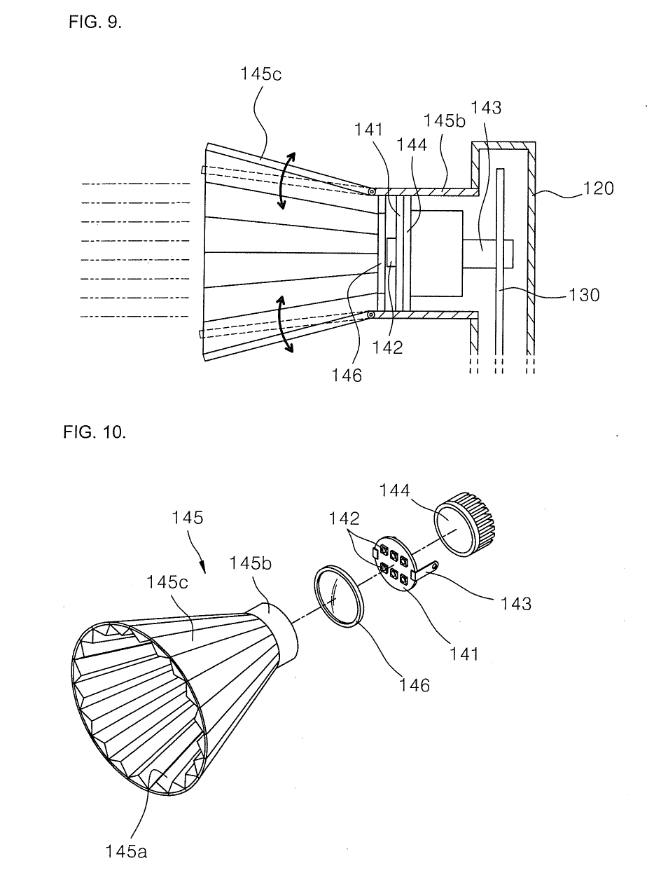

FIG. 7;

FIG. 9 is a cross-sectional view of the unitary LED modules shown in FIG. 7; and

FIG. 10 illustrates another example of a board shown in FIG. 8, having a circular shape.

### DETAILED DESCRIPTION OF THE INVENTION

Hereinafter, embodiments of the present invention will be described in detail with reference to the accompanying drawings.

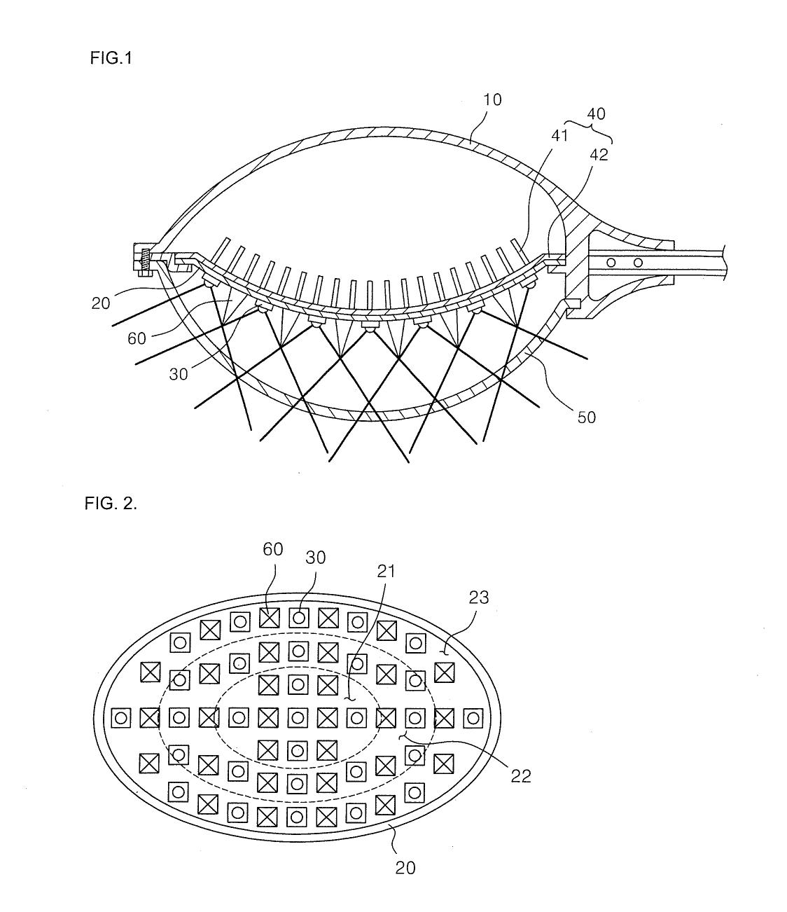

FIG. 1 illustrates an LED street lamp according to an embodiment of the present invention, and FIG. 2 illustrates LEDs and diffusing members arranged on a board of the LED street lamp shown in FIG. 1.

Referring to FIGS. 1 and 2, the LED street lamp according to the illustrated embodiment includes a case 10 provided at a front end of a post, a board 20 provided within the case 10 and having a plurality of LEDs 30 mounted thereon, and heat dissipating units 40 dissipating heat generated when the LEDs 30 emit light.

The case 10 has a space in which the board 20 and the heat dissipation units 40 are mounted, and an opening formed on one side surface thereof. The cover 50 made of glass or a transparent resin material to allow the light emitted from the LEDs to be transmitted, is coupled to the opening.

The board 20 is convexly formed, and the LEDs 30 are arranged on the convex external surface of the board 20 to be spaced apart from each other. Diffusing members 60 diffusing the light emitted from the LEDs 30 are provided between each of the LEDs 30 spaced apart from each other.

The plurality of LEDs 30 are provided by luminance level and are arranged on the board 20 such that the luminance may increase gradually from the center to the edge of the board 20.

Specifically, referring to FIG. 2, a 1-watt (W) LED is arranged at a first region 21 corresponding to the central portion of the board 20, and a 2-W LED is arranged at a second region 22 corresponding to a surrounding area of the central portion of the board 20. In addition, a 3-W LED is arranged at a third region 23 corresponding to an edge area of the board 20. In consideration of light-emitting characteristics of the LEDs 30, such arrangement of LEDs 30 may compensate for a low luminance level at the edge of the board 20, compared to the central portion of the board 20.

The LEDs 30 used have an illumination angle in the range of the range of between 50° and 60°.

The diffusing members 60 are made of glass or a transparent resin capable of transmitting the light beams emitted from the LEDs 30, and protrude from the board 20 in a shape of polyhedron having multiple-sided planar surfaces.

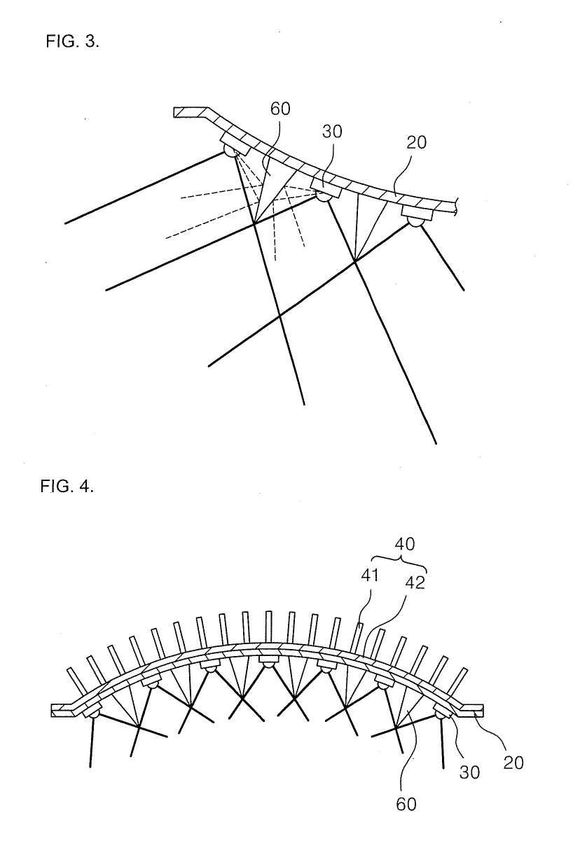

Referring to FIG. 3, the diffusing members 60 protrude to a height at which light beams of two neighboring LEDs 30 overlap each other. Accordingly, the light beams irradiated into the diffusing members 60 are refracted by the multiple-sided polyhedral surfaces a number of times to then be diffused while passing through the polyhedral diffusing members 60.

The heat dissipation units 40 dissipate heat by absorbing the heat generated when the LEDs 30 emit light. In order to enlarge a surface area, a heat dissipating plate 42 having a plurality of heat dissipating fins 41 formed thereon may be generally used. Preferably, the heat dissipating plate 42 is made of aluminum foam to further enlarge the surface area, thereby improving heat dissipation efficiency.

The operation and effects of the aforementioned LED street lamp according to the illustrated embodiment will now be described.

The LEDs 30 are supplied with power to emit light. Since the plurality of LEDs 30 are arranged on the convex external surface of the board 20, light beams are emitted from the plurality of LEDs 30 in a direction perpendicular to the normal line of the external surface, so that an illuminated area of the LED street lamp can be enlarged. However, the luminance of the illuminated area is not reduced.

That is to say, since the plurality of LEDs 30 having different luminance levels are arranged such that the luminance gradually increases from the center to the edge of the board 20. The light beams of low luminance level LEDs 30 arranged at the central portion of the board 20 are irradiated into the central portion of the enlarged illuminated area of the LED street lamp in an overlapping manner, thereby improving the luminance. In addition, the light beams of high luminance level LEDs 30 arranged at the edge of the board 20 are irradiated into the edge of the board 20 with the enlarged illuminated area of the LED street lamp, thereby improving the luminance.

Therefore, even if the illuminated area of the LED street lamp is enlarged, the luminance is not reduced, so that a blind zone may not be produced between adjacent street lamps.

That is to say, according to the present invention, the LED street lamp is configured such that high-luminance level LEDs are arranged at the edge of the board to provide for efficient light-emitting characteristics.

In addition, the light beams irradiated into the edge of the illuminated area at a predetermined illumination angle are reflected, refracted and diffused by the multiple-sided polyhedral surfaces of each of the diffusing members 60 provided between the LEDs 30. Even the light beams that are not effective because they are irradiated into the illuminated area at an angle exceeding the predetermined illumination angle can be diffused by the diffusing members 60.

Therefore, the light beams between each of the LEDs 30 are also diffused by the diffusing members 60 to then be illuminated into areas between each of the LEDs 30, point light sources formed on the board 20 by the LEDs 30 arranged at regular intervals become surface light sources, so that the luminance is improved. In addition, the number of the LEDs 30 arranged on the board 20 can be reduced by installing diffusing members, thereby reducing the manufacturing cost of the LED street lamp.

FIG. 4 illustrates another example of a board of the LED street lamp shown in FIG. 1.

Referring to FIG. 4, another exemplary board has a concavely formed surface. In the illustrated board, the plurality of LEDs 30 are arranged on the convex internal surface of the board 20 at regular intervals.

Here, the LEDs 30 are arranged such that the luminance levels gradually increase from the center of the concave internal surface of the board 20 to the edge of the board 20. An illuminated area can also be enlarged by the LEDs 30 arranged on the concave internal surface. That is to say, the light beams emitted from the LEDs 30 are irradiated in a direction perpendicular to the normal line of the concave internal surface, and the illuminated area can be enlarged by the LEDs 30 positioned at the edge of the concave internal surface. Even if the illuminated area is enlarged, the luminance of the enlarged illuminated area is not reduced owing to the high-luminance level LEDs installed at the edge of the concave internal surface.

The diffusing members 60 may perform the same function as described above.

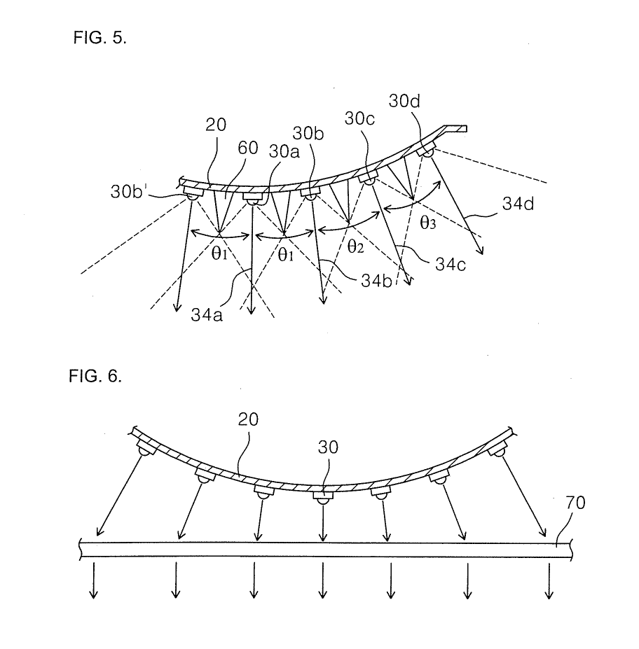

FIG. 5 illustrates an LED street lamp according to another embodiment of the present invention.

Referring to FIG. 5, the LED street lamp according to the illustrated embodiment includes a board 20, a plurality of LEDs 30 mounted on the board 20, and diffusing members 60 installed between each of the LEDs 30. Although not shown, heat dissipation units for dissipating heat may be provided on a top surface.

In the LED street lamp according to the illustrated embodiment, the LEDs 30 have the same luminance level, while beam angles between each of the LEDs 30 are different.

More specifically, assuming that lines passing from the LEDs 30 to the center of beam angles of light illuminated are referred to as optical center lines 34 and an angle formed by the optical center lines 34 of two adjacent LEDs 30 is a beam angle θ, the beam angle θ between the two adjacent LEDs 30 decreases gradually from the central portion to the edge of the board 20.

Referring to FIG. 5, when the LEDs 30 arranged at the central portion of the board 20 is referred to a first LED 30a, and the LEDs 30 arranged in a direction away from the central portion to the edge of the board 20 are referred to as second to fourth LEDs 30b, 30c, and 30d, respectively, the board 20 is formed to be downwardly convex. In order to form the overall illumination angle of the LED street lamp at an angle in the range of between 120° and 150°, the optical center lines 34 of the LEDs 30 positioned closer to the edge of the board 20 may form a greater angle with respect to the perpendicular line.

When the optical center lines of the respective LEDs 30a, 30b, 30c, and 30d are first to fourth optical center lines 34a, 34b, 34c, and 34d, a beam angle formed between the first optical center line 34a and the second optical center line 34b may be referred to as a first beam angle θ₁, a beam angle formed between the second optical center line 34b and the third optical center line 34c may be referred to as a second beam angle θ₂, and a beam angle formed between the third optical center line 34c and the fourth optical center line 34d may be referred to as a third beam angle θ₃. With respect to the magnitude of beam angle, the first beam angle θ₁ is greatest, and the beam angle gradually decreases in the order of the second and third beam angles θ₂ and θ₃. That is, the third beam angle θ₃ is smallest.

When the beam angle decreases, the overlapping area of the light beams emitted from the LEDs 30 becomes enlarged, so that the luminance over the illuminated area may increase. Accordingly, a luminance deviation in the entire illuminated area can be effectively reduced.

Although not illustrated in this embodiment, separate reflection sheets for adjusting optical angles of light beams emitted from the respective LEDs may further be provided on the board, and the optical angles of light beams emitted from the respective LEDs can be adjusted over the entire area illuminated by the LEDs by rotating the reflection sheets.

That is to say, the luminance of the illuminated area can be increased by reducing the optical angle using the reflection sheet. On the contrary, the luminance of the illuminated area can be decreased by enlarging the illuminated area by increasing the optical angle using the reflection sheet.

As shown in FIG. 6, a diffusion lens 70 is installed under the board 20 to make the light emitted from the LEDs 30 uniformly diffused over the entire illuminated area, thereby making the overall luminance levels uniform.

FIGS. 7 through 9 illustrate an LED street lamp according to another embodiment of the present invention, including a plurality of LED modules.

The LED street lamp 100 includes a case 120 provided at a front end of a lamp post 110 fixed on a ground surface, a second board 141 provided inside the case 120 and supplied with power from the second board 141, and a plurality of LED modules 140 each having an LED receiving the power from the second board 141 to emit light.

In particular, the LED modules 140 are detachably formed to be attached to and detached from a first board 130.

In the LED modules 140, a plurality of LEDs 142 are arranged on the second board 141. In addition, each of the LED modules 140 may include a fixing electrode terminal 143 provided on the second board 141 and coupled to the first board 130 to supply the second board 141 with power, a heat dissipating plate 144 provided in the rear of the second board 141 to emit heat generated from LEDs 142, a reflection shade 145 provided in front of the second board 141 to adjust an illuminated area of LED light beams, and a diffusion lens 146 provided in front of the LEDs 142 and capable of collecting or diffusing the LED light beams. The second board 141 may have a rectangular shape. Alternatively, as shown in FIG. 10, the second board 141 may have a circular shape. However, the present invention does not limit the shape of the second board 141 to those illustrated.

The reflection shade 145, the diffusion lens 146, and the heat dissipating plate 144 are shaped to correspond to the second board 141.

The reflection shade 145 includes coupling portions 145b closely adhered to opposite edges of the second board 141 and coupled to the case 120, and reflecting portions 145c formed radially so as to enlarge from edges of the coupling portions 145b and gradually increase an interior distance between the coupling portions 145b. The reflecting portions 145c reflect LED light beams.

Each of the reflecting portions 145c has an uneven portion 145a formed on its inner surface to reflect the LED light beams to be diffused. The reflecting portions 145c are installed at the coupling portion 145b to be rotatable at a predetermined angle. Accordingly, the reflecting portions 145c are rotated with respect to the coupling portion 145b to adjust beam angles of the LEDs 142 by controlling the interior surface between the reflecting portions 145c, thereby controlling the intensity of illumination of the ground surface (see FIG. 9).

Meanwhile, as shown in FIG. 10, when the second board 141 has a circular shape, the coupling portion 145b is circular, and the reflecting portion 145c is cone-shaped. Preferably, the reflecting portion 145c may be divided into multiple parts to then be rotatably installed along the edge of the coupling portion 145b.

The case 120 includes a through-hole (not shown) formed in its front surface to allow the fixing electrode terminal 143 of the second board 141 to extend through the case 120 to then be coupled to the first board 130. In addition, the case 120 has one side surface formed to convexly protrude.

The first board 130 is curved to correspond to the curved case 120 so as to be housed in the case 120. The LED modules 140 are coupled to convex portions of the first board 130. Accordingly, it is possible to enlarge an illuminated area of the LED street lamp including the plurality of LED modules 140.

Alternatively, the case 120 and the first board 130 may not be curved. That is to say, convex portions may not be formed in the case 120 and the first board 130. In this case, when the LED modules 140 are coupled to the first board 130, they may be obliquely coupled to the first board 130 so as to irradiate LED light beams radially around the central portion of the first board 130.

As the illuminated area of the LED street lamp is enlarged, irradiation distances of the LED modules become longer toward the edge of the case 120. In addition, as the illuminated area of the LED street lamp is enlarged, the luminance levels over the entire illuminated area of the LED street lamp gradually decrease from the center to the edge of the case 120.

To compensate for such disadvantages, as illustrated in the above embodiments, the plurality of LEDs having different luminance levels are arranged on first board 130, such that the luminance gradually increases from the center to the edge of the first board 130, thereby uniformly irradiating the LED light beams into the enlarged illuminated area.

In order to make the luminance over the entire illuminated area uniform, like in the embodiment illustrated in FIG. 5, the LED modules 140 are arranged such that the luminance over the entire illuminated area gradually increases from the center to the edge of the first board 130 to enlarge the overlapping area of the light beams, thereby preventing the luminance of the edge of the first board 130 from decreasing.

The LED street lamp can be applied to a street lamp used for illumination of a road. In addition, the conventional street lamp can also be used for the inventive LED street lamp by replacing only a lamp part. Therefore, the LED street lamp according to the present invention is highly advantageous in view of industrial applicability.

Although exemplary embodiments of the present invention have been described in detail hereinabove, it should be understood that many variations and modifications of the basic inventive concept herein described, which may appear to those skilled in the art, will still fall within the spirit and scope of the exemplary embodiments of the present invention as defined by the appended claims.

What is claimed is:

1. A light emitting diode (LED) street lamp comprising:
a case provided at a front end of a lamp post;
a board provided inside the case and having a plurality of LEDs spaced apart from each other; and
heat dissipation units closely adhered to the board and dissipating heat generated when the LEDs emit light,
wherein the plurality of LEDs have different luminance levels from each other, the luminance levels gradually increase from the center of the board to the edge of the board, and diffusing members diffusing the light generated from the plurality of LEDs are provided on board portions corresponding to areas between each of the plurality of LEDs.

2. The LED street lamp of claim 1, wherein the board is convexly formed and each of the LEDs is installed on a convex external surface.

3. The LED street lamp of claim 1, wherein the board is concavely formed and each of the LEDs is installed on a concave internal surface.

4. The LED street lamp of claim 2 or 3, wherein the diffusing members are made of a transparent material in the form of a polyhedron such that some of the light beams emitted from the plurality of LEDs are diffused, and protrude from the board until it reaches a position where the light beams from neighboring ones among the plurality of LEDs overlap each other.

5. A light emitting diode (LED) street lamp comprising:
a case provided at a front end of a lamp post;
a board provided inside the case and having a plurality of LEDs spaced apart from each other;
heat dissipation units closely adhered to the board and dissipating heat generated when the LEDs emit light,
wherein assuming that a line passing from the LEDs to the center of beam angles of light illuminated is referred to as an optical center line and an angle between optical center lines of two adjacent LEDs is a beam angle, the beam angle between the two adjacent LEDs decreases gradually from the central portion to the edge of the board.

6. The LED street lamp of any one of claims 1 and 5, further comprising a diffusion lens installed under the board and collecting the light emitted from the LEDs and uniformly diffusing the collected light into the illuminated area.
